(19) United States
(12) Patent Application Publication
(10) Pub. No.: US 2015/0194537 A1
(43) Pub. Date: Jul. 9, 2015

(54) MULTI-LAYER INTER-GATE DIELECTRIC STRUCTURE

(71) Applicant: Spansion LLC, Sunnyvale, CA (US)

(72) Inventors: Chun CHEN, San Jose, CA (US); Shenqing Fang, Fremont, CA (US)

(73) Assignee: Spansion LLC, Sunnyvale, CA (US)

(21) Appl. No.: 14/149,628

(22) Filed: Jan. 7, 2014

(51) Int. Cl. H01L 29/792; H01L 21/311; H01L 29/51; H01L 21/28; H01L 29/66; H01L 29/423

(52) U.S. Cl. CPC H01L 29/792; H01L 29/66825; H01L 29/42344; H01L 29/513; H01L 29/518; H01L 21/28282; H01L 21/31111

(57) ABSTRACT

A semiconductor device having a first gate stack on a substrate is disclosed. The first gate stack may include a first gate conductor over a first gate dielectric structure. A dielectric structure can be formed over the first gate stack and the substrate. The dielectric structure layer can include four or more layers of two or more dielectric films disposed in an alternating manner. The dielectric structure can be selectively etched to form an inter-gate dielectric structure. A second gate conductor can be formed over a second gate dielectric structure, adjacent to the inter-gate dielectric structure. A dielectric layer can be formed over the substrate, the first and second gate conductors, and the inter-gate dielectric structure. The first gate conductor may be used to make a memory gate and the second gate conductor can be used to make a select gate of a split-gate memory cell.

### BACKGROUND

1. Technical Field

This disclosure relates generally to improved semiconductor devices and methods for making such devices.

2. Related Art

Split-gate semiconductor devices typically include a number of gates that are insulated from one another by inter-gate dielectric structures. FIG. 2A illustrates a conventional split-gate semiconductor device 200 formed on a substrate 202. Semiconductor device 200 includes a first gate 210 disposed over a gate dielectric structure 214, a second gate 208 disposed over a gate dielectric structure 212, and a single-layer inter-gate dielectric structure 216 disposed between the two gates. The inter-gate dielectric structure 216 may be made of, but is not limited to, silicon dioxide. FIG. 2B illustrates the same semiconductor device 200 after it has gone through further wet etch or wet clean stages during the fabrication process. In this case, the inter-gate dielectric structure 216 is shown with a portion removed at region 218, creating a gap between gate 208 and gate 210. In subsequent stages of fabrication, this gap may get filled with a lower quality dielectric 220, as shown in FIG. 2C, or undesired chemical residues, or may even form voids. Consequently, the electrical isolation between the two gates is weakened, leading to excessive leakage current and possibly an early dielectric breakdown between the two gates.

FIGS. 3A-3C illustrate another conventional split-gate semiconductor device 300, similar to semiconductor device 200 depicted in FIGS. 2A-2C. However, the inter-gate dielectric structure 316 comprises three layers of different dielectric films such as silicon dioxide/silicon nitride/silicon dioxide. FIG. 3B depicts portions of the inter-gate dielectric structure removed after the semiconductor device depicted in FIG. 3A has gone through further wet etch or wet clean stages during the fabrication process. In FIG. 3B, the dielectric films of the inter-gate dielectric structure are shown to be removed in an uneven manner because etch rates vary based on the wet chemicals used to etch the specific dielectrics. Once again, the gap created between gate 308 and gate 310 may get filled with a lower quality dielectric 320, as shown in FIG. 3C. Undesired chemical residues or even voids may result, weakening the electrical isolation between the two gates. Such undesirable consequences may lead to excessive leakage current and possibly an early dielectric breakdown between the two gates.

What is needed are split-gate semiconductor devices and methods for manufacturing them that result in inter-gate structures that do not suffer from the above shortcomings.

### BRIEF SUMMARY OF THE INVENTION

According to various embodiments, a method of making a semiconductor device and its resulting structure are described. According to the method, a first gate stack is formed on a substrate. The gate stack may include a first gate conductor over a first gate dielectric structure. A dielectric structure can be formed over the first gate stack and the substrate. The dielectric structure layer can include four or more layers of two or more dielectric films disposed in an alternating manner. The dielectric structure can be selectively etched to form an inter-gate dielectric structure. A second gate conductor can be formed over a second gate dielectric structure, adjacent to the inter-gate dielectric structure. A dielectric layer can be formed over the substrate, the first and second gate conductors, and the inter-gate dielectric structure.

A semiconductor device is also described. The semiconductor device may include a substrate, a first gate structure, a second gate structure and an inter-gate dielectric structure. The first gate structure may comprise a first gate conductor and a first gate dielectric structure disposed between the first gate conductor and the substrate. The second gate structure may comprise a second gate conductor and a second gate dielectric structure disposed between the second gate conductor and the substrate. The inter-gate dielectric structure may be disposed between the first gate structure and the second gate structure, and include four or more layers of two or more different alternating dielectric films. The resulting inter-gate dielectric structure does not suffer from the shortcomings described above.

Further features and advantages of embodiments of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to a person skilled in the relevant art(s) based on the teachings contained herein.

### BRIEF DESCRIPTION OF THE DRAWINGS/FIGURES

Embodiments of the invention will now be described, by way of example only, with reference to the accompanying schematic drawings in which corresponding reference symbols indicate corresponding parts. Further, the accompanying drawings, which are incorporated herein and form part of the specification, illustrate embodiments of the present invention, and, together with the description, further serve to explain the principles of the invention and to enable a person skilled in the relevant art(s) to make and use the invention.

FIG. 1 illustrates an example split-gate non-volatile memory cell according to various embodiments.

FIGS. 2A-2C depicts a cross-section of a split-gate semiconductor device with a single-layer inter-gate dielectric structure at various points during its manufacture.

FIGS. 3A-3C depicts a cross-section of a split-gate semiconductor device with a three-layer inter-gate dielectric structure at various points during its manufacture.

FIGS. 4A-4E depict a cross-section of a semiconductor device at various points during its manufacture according to various embodiments.

FIG. 5 is a flowchart depicting a method of manufacturing a semiconductor device according to various embodiments.

FIGS. 6A-6E depict a cross-section of a semiconductor device at various points during its manufacture according to various embodiments.

The features and advantages of embodiments of the present invention will become more apparent from the detailed description set forth below when taken in conjunction with the drawings. In the drawings, like reference numbers generally indicate identical, functionally similar, and/or structurally similar elements.

### DETAILED DESCRIPTION OF THE INVENTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Before describing the various embodiments in more detail, further explanation shall be given regarding certain terms that may be used throughout the descriptions.

The term “etch” or “etching” is used herein to generally describe a fabrication process of patterning a material, such that at least a portion of the material remains after the etch is completed. For example, it should be understood that the process of etching silicon involves the steps of patterning a masking layer (e.g., photoresist or a hard mask) above the silicon, and then removing the areas of silicon no longer protected by the masking layer. As such, the areas of silicon protected by the mask would remain behind after the etch process is complete. However, in another example, etching may also refer to a process that does not use a mask, but still leaves behind at least a portion of the material after the etch process is complete.

The above description serves to distinguish the term “etching” from “removing.” When etching a material, at least a portion of the material remains behind after the process is completed. In contrast, when removing a material, substantially all of the material is removed in the process. However, in some embodiments, ‘removing’ is considered to be a broad term that may incorporate etching.

During the descriptions herein, various regions of the substrate upon which the field-effect devices are fabricated are mentioned. It should be understood that these regions may exist anywhere on the substrate and furthermore that the regions may not be mutually exclusive. That is, in some embodiments, portions of one or more regions may overlap. Although up to three different regions are described herein, it should be understood that any number of regions may exist on the substrate and may designate areas having certain types of devices or materials. In general, the regions are used to conveniently describe areas of the substrate that include similar devices and should not limit the scope or spirit of the described embodiments.

The terms “forming,” “form,” “deposit,” or “dispose” are used herein to describe the act of applying a layer of material to the substrate or another layer of material. Such terms are meant to describe any possible layer-forming technique including, but not limited to, thermal growth, sputtering, evaporation, chemical vapor deposition, epitaxial growth, electroplating, etc. According to various embodiments, for instance, deposition may be performed according to any appropriate well-known method. For instance, deposition can comprise any process that grows, coats, or transfers material onto a substrate. Some well-known technologies include physical vapor deposition (PVD), chemical vapor deposition (CVD), electrochemical deposition (ECD), molecular beam epitaxy (MBE), atomic layer deposition (ALD), and plasma-enhanced CVD (PECVD), amongst others.

The “substrate” as used throughout the descriptions is most commonly thought to be silicon. However, the substrate may also be any of a wide array of semiconductor materials such as germanium, gallium arsenide, indium phosphide, etc. In other embodiments, the substrate may be electrically non-conductive such as a glass or sapphire wafer.

As used herein, “mask” may comprise any appropriate material that allows for selective removal (e.g., etching) of an unmasked portion a material. According to some embodiments, masking structures may comprise a photoresist such as Poly(methyl methacrylate) (PMMA), Poly(methyl glutarimide) (PMGI), a Phenol formaldehyde resin, a suitable epoxy, etc.

Before describing such embodiments in more detail, it is instructive to present an example memory cell and environment in which the present embodiments may be implemented.

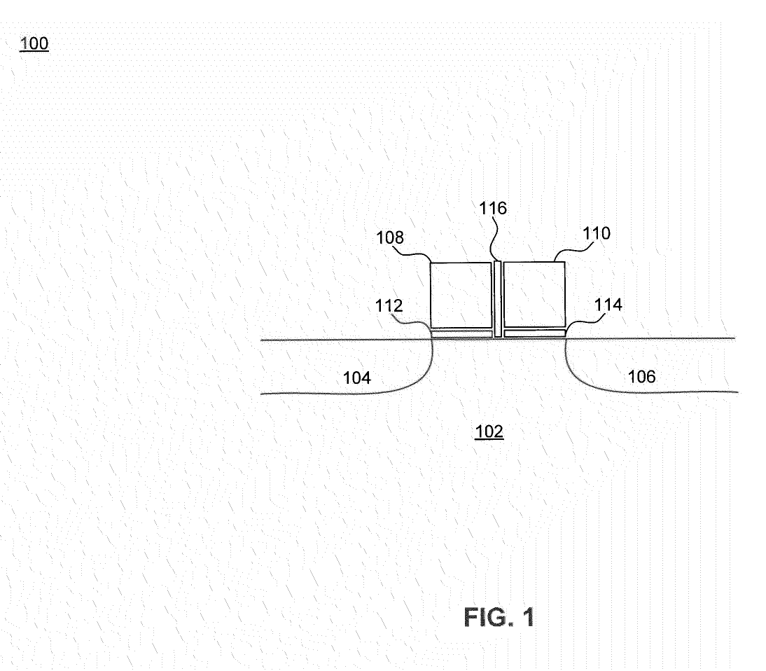

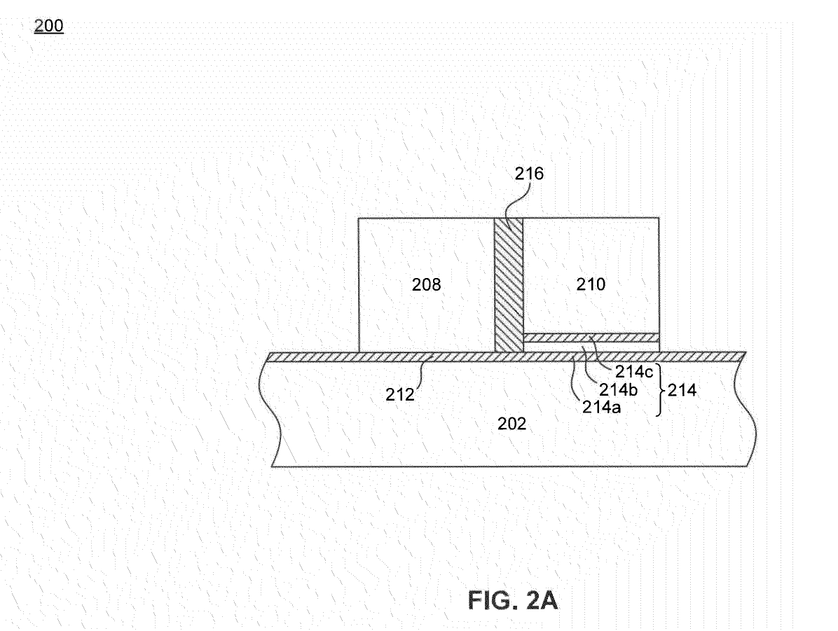

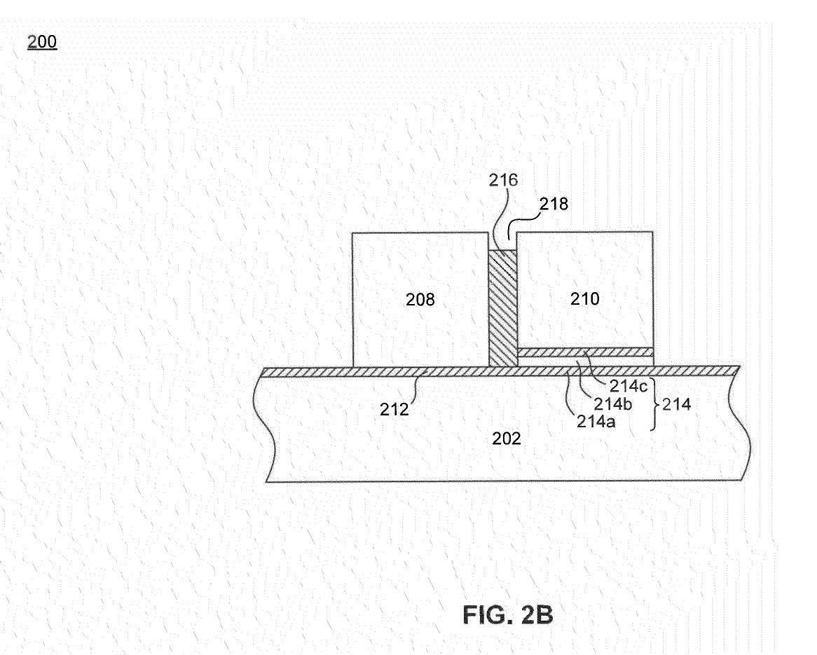

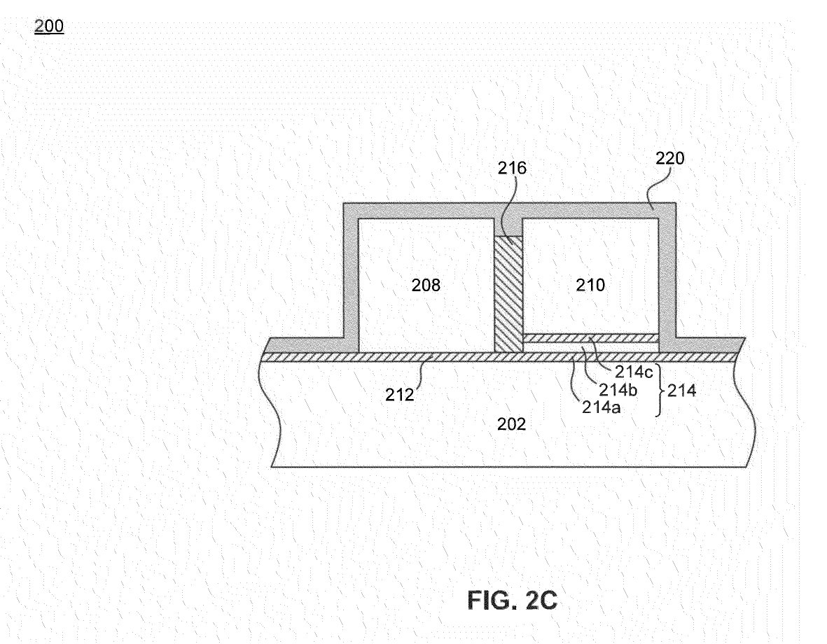

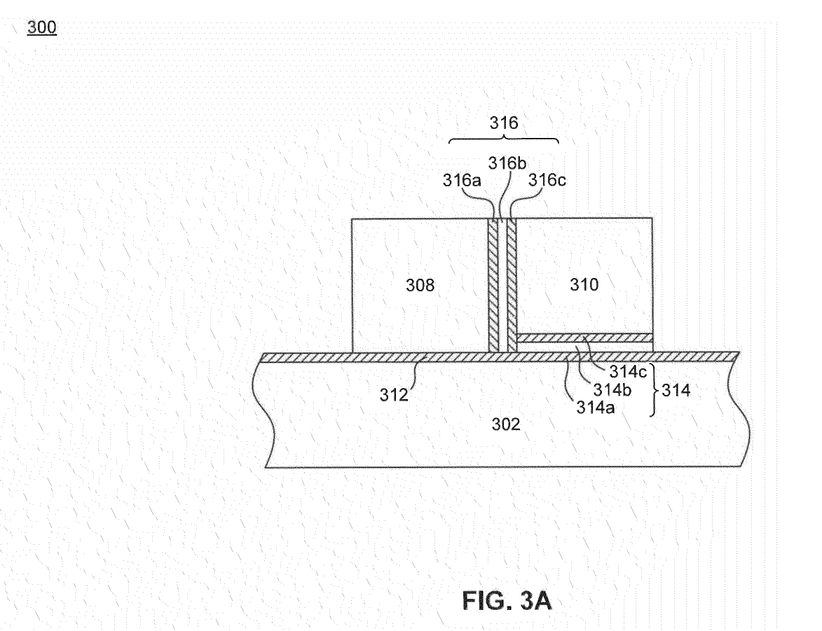

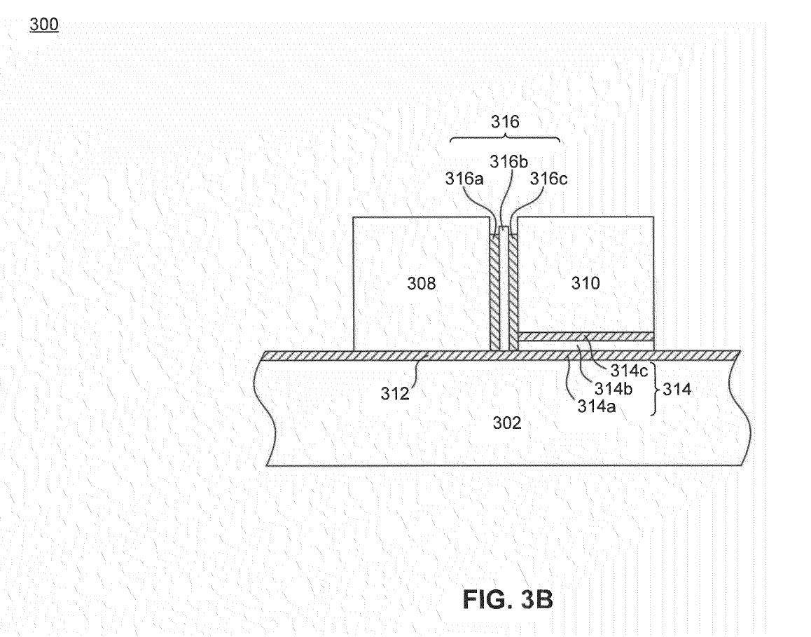

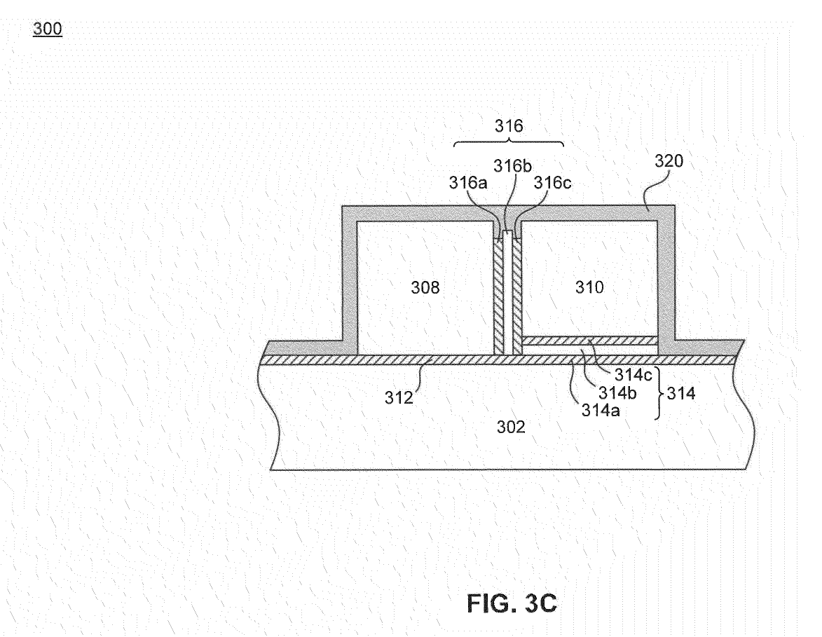

FIG. 1 illustrates a split-gate non-volatile memory cell 100. Memory cell 100 is formed on a substrate 102, such as silicon. Substrate 102 is commonly p-type or a p-type well while a first doped source/drain region 104 and a second doped source/drain region 106 are n-type. However, it is also possible for substrate 102 to be n-type while regions 104 and 106 are p-type.

Memory cell 100 includes two gates, a select gate 108, which is formed adjacent to a memory gate 110. Each gate may comprise a gate conductor such as a doped poly layer formed by well-known, for example, deposit and etch techniques to define the gate structure. Select gate 108 is disposed over a dielectric layer 112. Memory gate 110 is disposed over a dielectric 114 having one or more dielectric layers. In one example, dielectric 114 includes a charge-trapping silicon nitride layer sandwiched between two silicon dioxide layers to create a three-layer stack collectively and commonly referred to as “oxide/nitride/oxide” or “ONO.” Other dielectrics may include a silicon-rich nitride film, or any film that includes, but is not limited to, silicon, oxygen, and nitrogen in various stoichiometries. An inter-gate dielectric 116 is disposed between select gate 108 and memory gate 110 for electrical isolation between the two gates. In some examples, inter-gate dielectric 116 and dielectric 114 are the same dielectric, while other examples form one dielectric before the other (e.g., they can have different dielectric properties). As such, inter-gate dielectric 116 need not include the same film structure as dielectric 114. Regions 104 and 106 are created by implanting dopants using, for example, an ion implantation technique. Regions 104 and 106 form the source or drain of the split-gate transistor depending on what potentials are applied to each. In split-gate transistors, for convenience, region 104 is commonly referred to as the drain, while region 106 is commonly referred to as the source, independent of the relative biases. It is to be understood that this description is meant to provide a general overview of a common split-gate architecture and that, in actual practice, many more detailed steps and layers are provided to form the final memory cell 100.

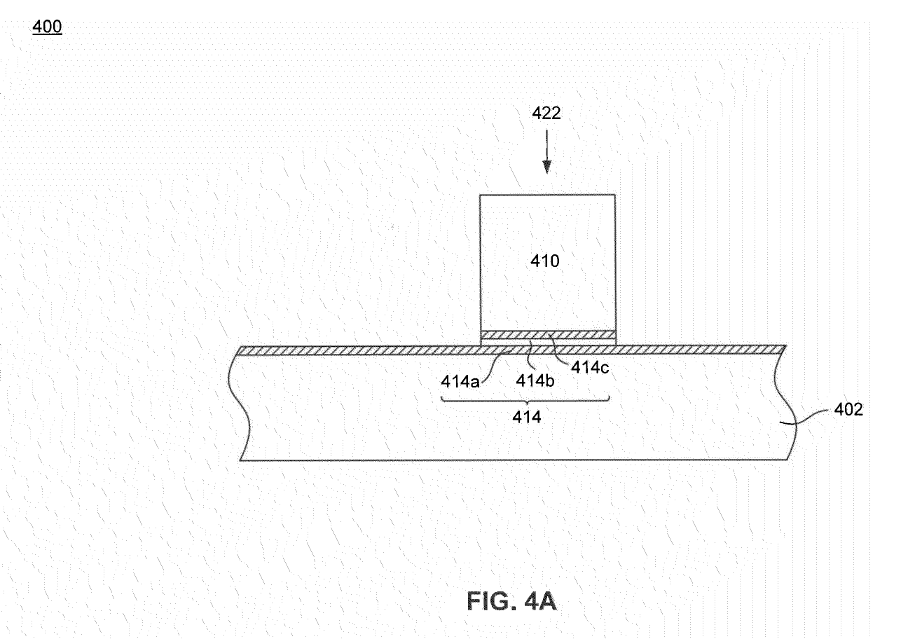

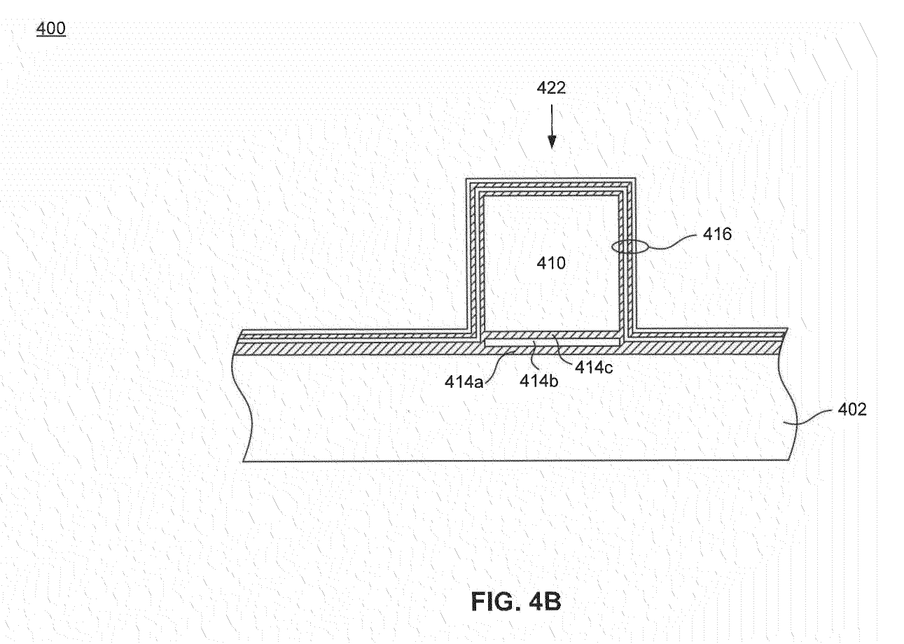

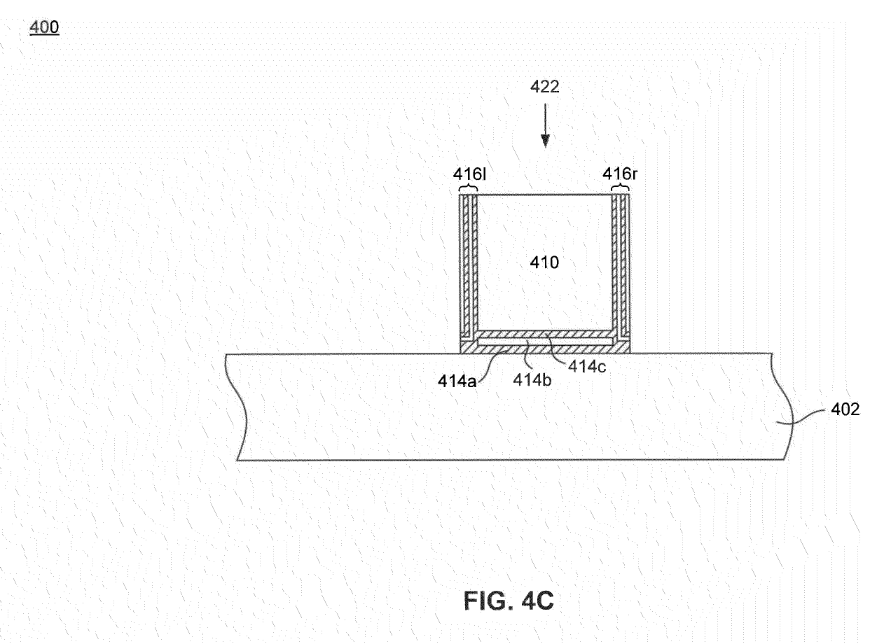

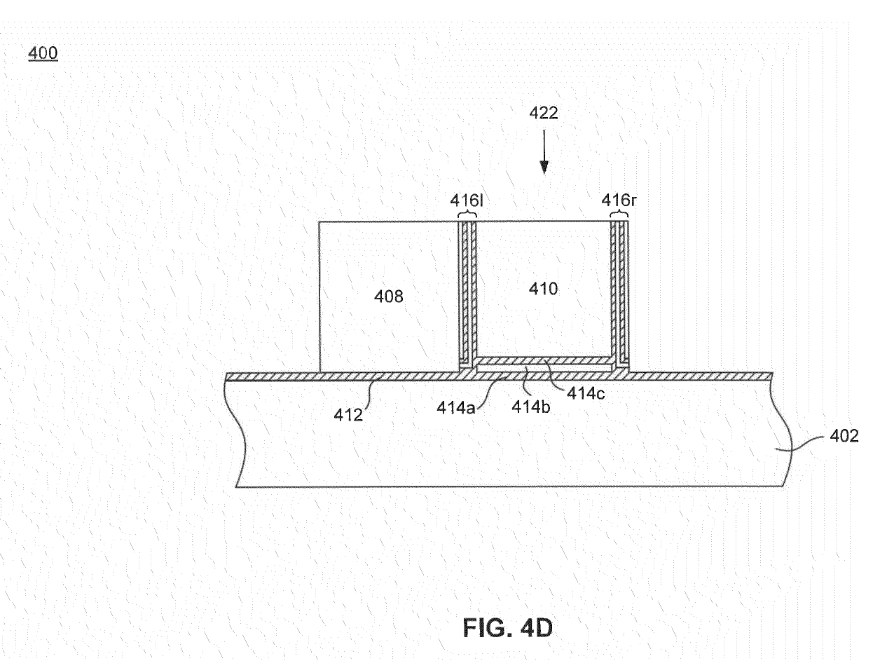

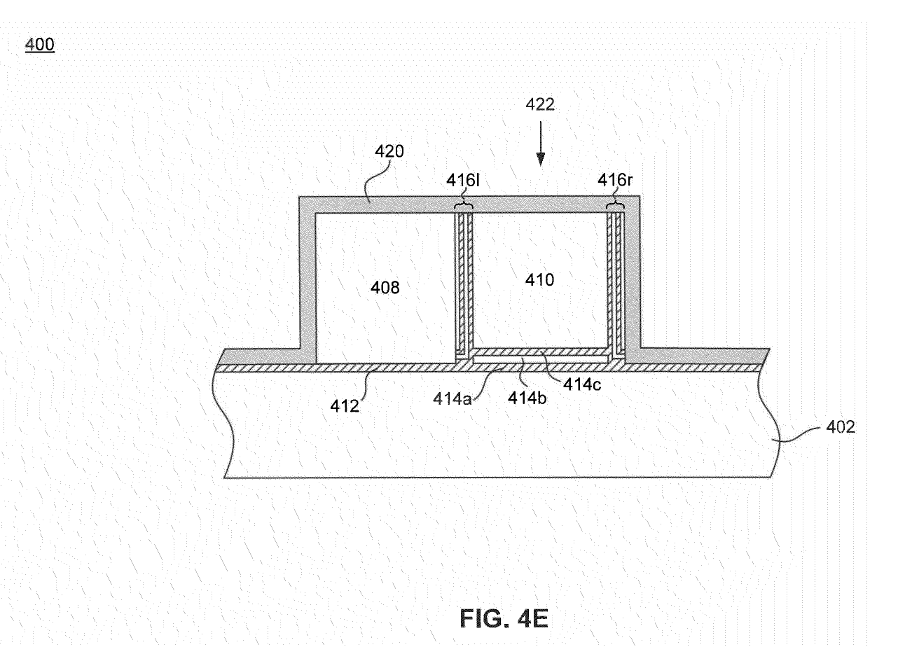

The method for manufacturing the improved split-gate semiconductor devices, according to various embodiments, will now be described with respect to FIGS. 4A-4E, which depict a cross-section of a semiconductor device 400 at various stages during its production. In FIG. 4A, semiconductor device 400 is depicted as having a substrate 402. Gate stack 422 has been formed on top of the substrate 402 according to a number of known methods. For instance, U.S. patent application Ser. No. 13/715,577, which is hereby incorporated by reference in its entirety, discloses such a method of creating gate stack 422. The present disclosure is not limited to any particular method of producing gate stack 422. Indeed the spirit and scope of the invention includes any appropriate method for forming gate stack 422.

As can be seen in FIG. 4A, gate stack 422 includes a first gate conductor 410. The gate conductor 410 may comprise any suitable material such as polycrystalline silicon (“poly”). A gate dielectric structure 414 has been disposed above the substrate 402 and beneath the gate conductor 410. According to various embodiments, the gate dielectric structure comprises one or more layers of dielectric such as ONO, as described above. For instance, if device 400 will be used as a split-gate memory cell, the gate dielectric structure 414 may comprise a first dielectric layer 414a, a charge-trapping layer 414b, and a second dielectric layer 414c. Regardless of the specific composition of the gate dielectric structure 414, it preferably contains at least one charge-trapping layer 414b. The charge-trapping layer may be formed of a nitride or silicon rich nitride, and may include multiple layers of different nitrides according to some embodiments. Alternatively, the dielectric layer may comprise a single layer of dielectric material such as an oxide, nitride, or some combination thereof.

FIG. 4B depicts device 400 at a further point in the production process, where a dielectric structure 416 has been disposed over gate stack 422 and substrate 402 using, for example, in-situ film deposition. In FIG. 4B, the dielectric structure 416 is shown to comprise, but is not limited to, four layers of two different dielectric films disposed in an alternating manner such as “oxide/nitride/oxide/nitride” or “ONON”. Each of the different dielectric films of the dielectric structure 416 is formed to have a minimal thickness such that its wet etch rate is significantly less than its bulk etch rate. Additionally, adjacent layers of dielectric films of the dielectric structure 416 are chosen to have significantly different wet etch rates.

FIG. 4C depicts device 400 after portions of dielectric structure 416 have been selectively removed by, for example, etching, forming dielectric structures 4161 (left) and 416r (right) on the sidewalls of first gate conductor 410. FIG. 4D further illustrates a dielectric layer 412 formed on top of the substrate 402 according to a number of known methods. A second gate conductor 408 has also been formed, according to a number of known methods, adjacent to dielectric structure 4161 and on top of dielectric 412. Gate conductor 408 may be similarly formed adjacent to dielectric structure 416r. According to various embodiments, first gate conductor 410 may be used to make a memory gate and second gate conductor 408 to make a select gate of a split-gate memory cell. Disposed between the first and second gate conductors, dielectric structure 4161 thus forms a four-layer inter-gate dielectric structure.

FIG. 4E depicts device 400 at an even further point in the production process, where a dielectric layer 420 is formed over substrate 402, gate conductors 408 and 410, and dielectric structures 4161 and 416r. Dielectric layer 420 may be of lower quality than the dielectric films of dielectric structures 4161 and 416r. As can be seen in FIG. 4E, the four-layer inter-gate dielectric structure remains resistant to wet etch or wet clean stages prior to dielectric layer 420 being formed. This is attributed to the dielectric films of inter-gate dielectric structure having a minimal thickness such that their wet etch rates are significantly less than their bulk etch rates, and the adjacent dielectric films having significantly different wet etch rates. As a result, the four-layer inter-gate dielectric structure can provide strong electrical isolation and high dielectric breakdown voltage between the two gate conductors.

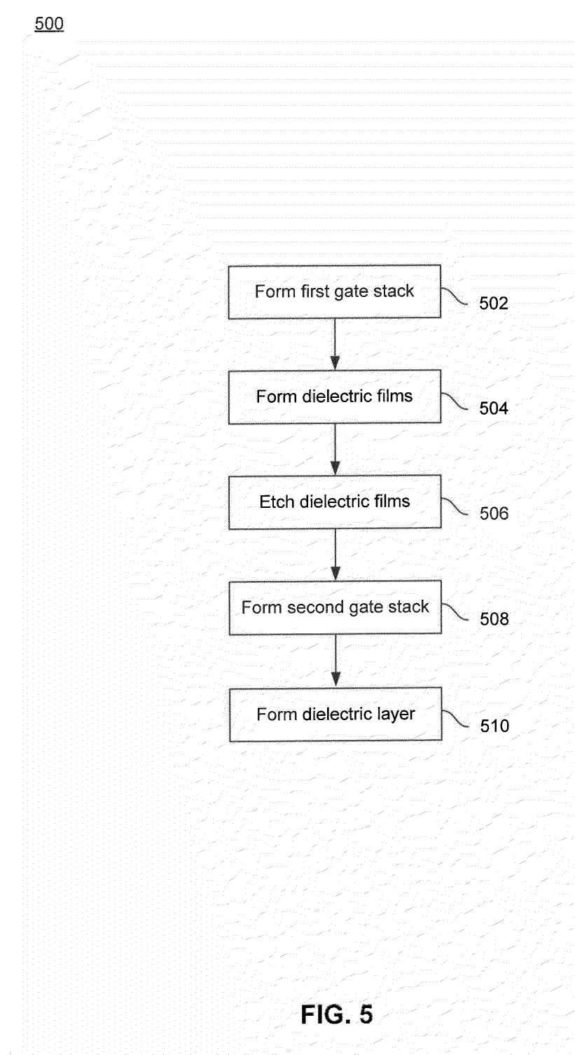

FIG. 5 depicts a method 500 of constructing a semiconductor device such as device 400 according to various embodiments. The discussion of FIG. 5 will make reference to FIGS. 4A-4E, but it should be understood that method 500 is not limited to the specific embodiments depicted in FIGS. 4A-4E, but is more generally applicable.

As shown in FIG. 5, method 500 begins at step 502 by forming a first gate stack (e.g., gate stack 422) on a substrate 402. Gate stack 422 include a gate conductor 410. Gate stacks 422 also includes a gate dielectric structure 414, which may comprise a first dielectric layer 414a, a charge-trapping layer 414b, and a second dielectric layer 414c. At step 504, dielectric structure 416 is formed over gate stack 422 and substrate 402. Dielectric structure 416 may include four or more layers of two or more different alternating dielectric films. At step 506, portions of the dielectric structure 416 are selectively removed to form dielectric structures 4161 and 416r, either of which may be used as the inter-gate dielectric structure. At step 508, a second gate stack is formed adjacent to either dielectric structure 4161 or 416r. The second gate stack include a gate conductor 408, which may be disposed on a gate dielectric structure 412. At step 510, a dielectric layer 420 is formed over substrate 402, gate conductors 408 and 410, and dielectric structures 4161 and 416r.

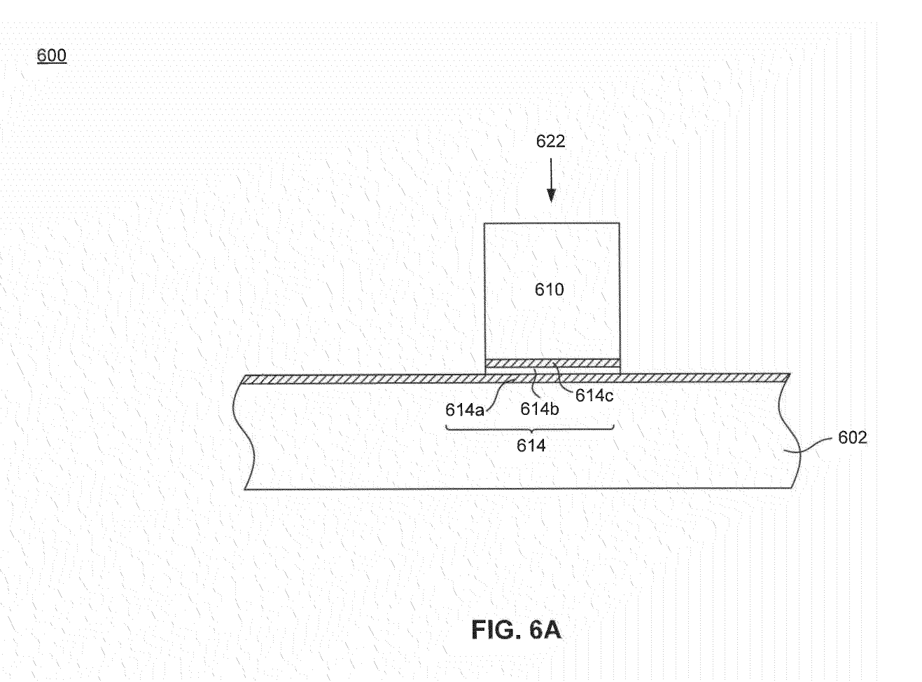

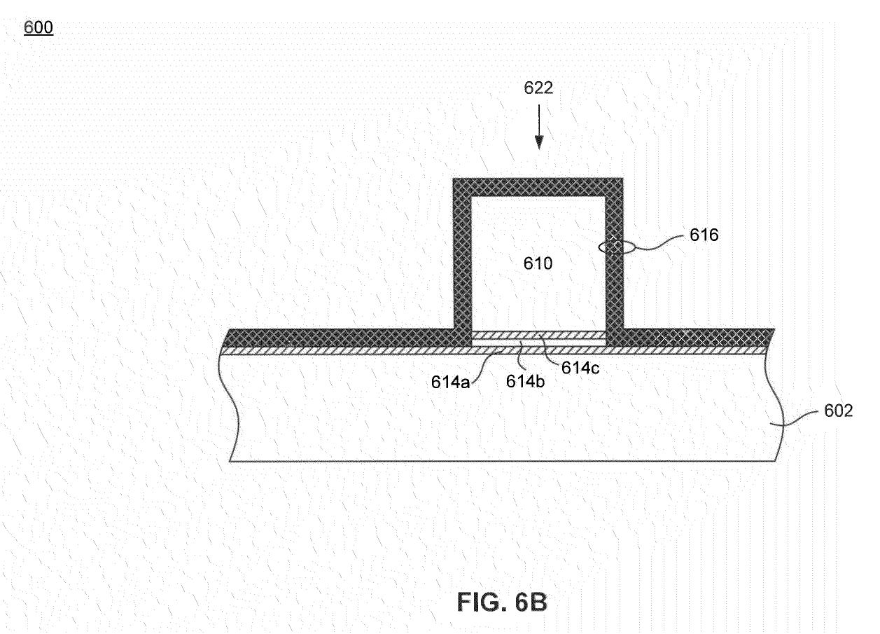

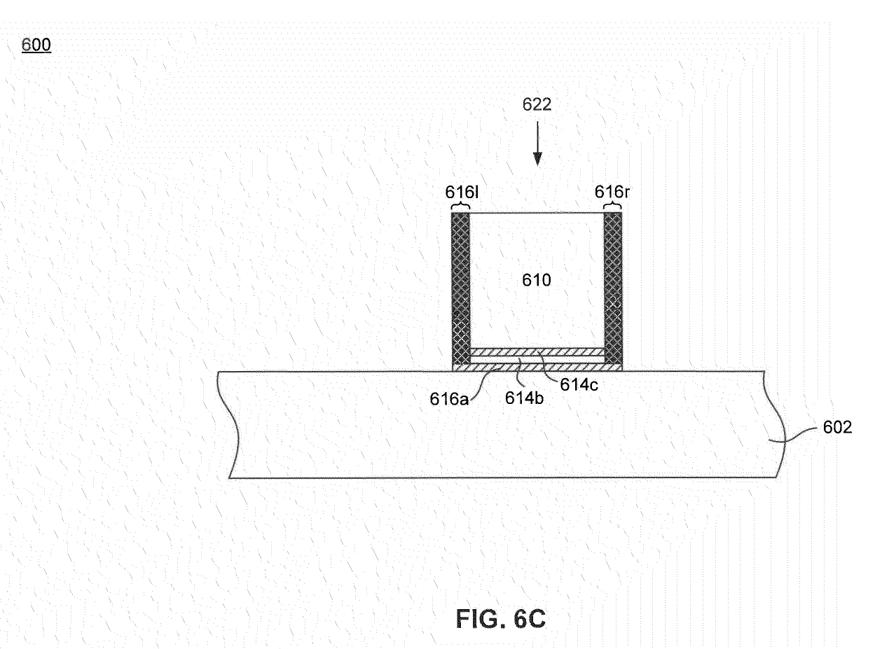

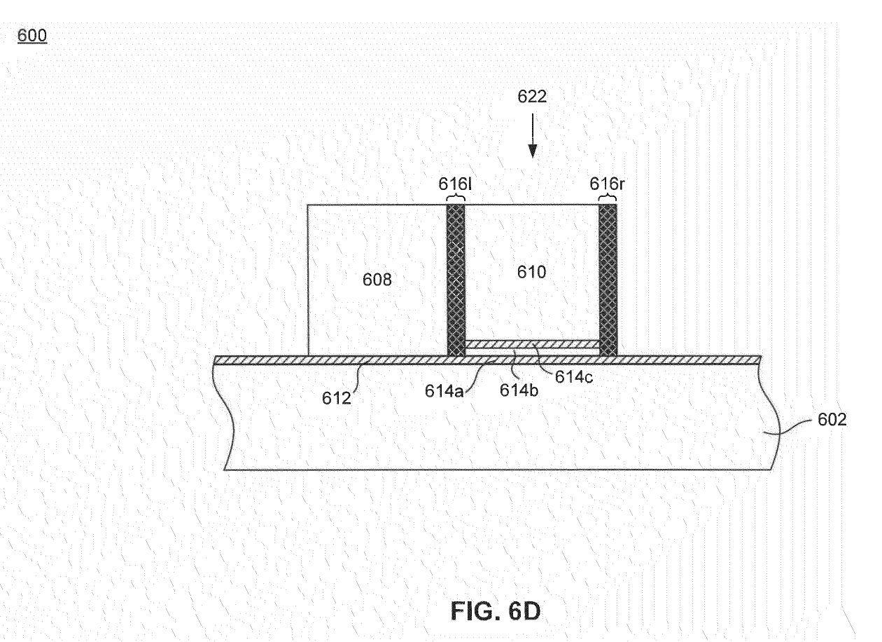

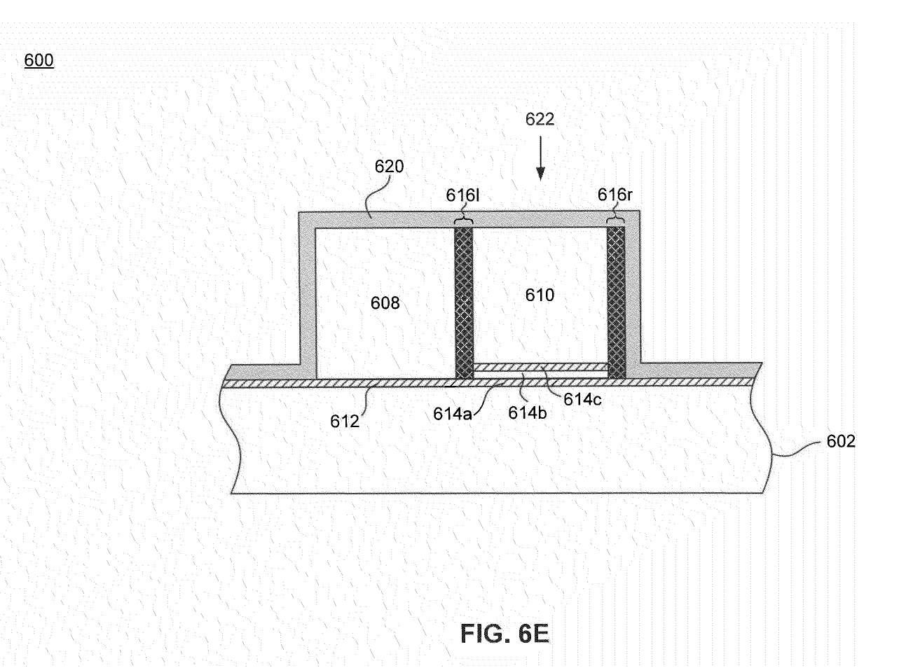

FIGS. 6A-6E depict a cross-section of semiconductor device 600 at various stages during its production according to various embodiments. As will be seen, while device 600 is the same as device 400 in a number ways, it differs in several other ways.

As can be seen in FIG. 6A, device 600—much like device 400—includes gate stack 622 formed on top of substrate 602 according to a number of known methods. Gate stack 622 includes a first gate conductor 610, which may comprise any suitable material such as poly. A gate dielectric structure 614 has been disposed above the substrate 602 and beneath the gate conductor 610. According to various embodiments, the gate dielectric structure comprises one or more layers of dielectric such as ONO, as described above. For instance, if device 600 will be used as a split-gate memory cell, the gate dielectric structure 614 may comprise a first dielectric layer 614a, a charge-trapping layer 614b, and a second dielectric layer 614c.

FIG. 6B depicts device 600 at a further point in the production process, where a dielectric structure 616 has been disposed over gate stack 622 and substrate 602 using, for example, in-situ film deposition. Different from device 400, but not explicitly shown in FIG. 6B, the dielectric structure 616 may comprise four or more layers of two or more different dielectric films disposed in an alternating manner. For example, dielectric structure 616 may comprise four alternating oxide and nitride films, i.e. “ONON,” or at least one farther layer of oxide film, or at least one further alternating pair of oxide/nitride films. Alternatively, dielectric structure 616 may comprise four alternating nitride and oxide films, i.e. “NONO,” or at least one further layer of nitride film, or at least one further alternating pair of nitride/oxide films. Similar to device 400, each of the different dielectric films of the dielectric structure 616 is formed to have a minimal thickness such that its wet etch rate is significantly less than its bulk etch rate. Additionally, adjacent layers of dielectric films of the dielectric structure 616 are chosen to have significantly different wet etch rates.

FIG. 6C depicts device 600 after portions of dielectric structure 616 have been selectively removed by, for example, etching, forming dielectric structures 6161 and 616r on the sidewalls of first gate conductor 610. FIG. 6D further illustrates a dielectric layer 612 formed on top of the substrate 602 according to a number of known methods. A second gate conductor 608 has also been formed, according to a number of known methods, adjacent to dielectric structure 6161 and on top of dielectric 612. Gate conductor 608 may be similarly formed adjacent to dielectric structure 616r. According to various embodiments, first gate conductor 610 may be used to make a memory gate and second gate conductor 608 to make a select gate of a split-gate memory cell. Disposed between the first and second gate conductors, dielectric structure 6161 thus forms a multi-layer inter-gate dielectric structure.

FIG. 6E depicts device 600 at an even further point in the production process, where a dielectric layer 620 is formed over substrate 602, gate conductors 608 and 610, and dielectric structures 6161 and 616r. Dielectric layer 620 may be of lower quality than the dielectric films of dielectric structures 6161 and 616r. As can be seen in FIG. 6E, the multi-layer inter-gate dielectric structure remains resistant to wet etch or wet clean stages prior to dielectric layer 620 being formed. Once again, this is attributed to the dielectric films of inter-gate dielectric structure having a minimal thickness such that their wet etch rates are significantly less than their bulk etch rates, and the adjacent dielectric films having significantly different wet etch rates. As a result, the multi-layer inter-gate dielectric structure can provide strong electrical isolation and high dielectric breakdown voltage between the two gate conductors.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

Embodiments of the present invention have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance. Additionally, it should be understood that none of the examples or explanations contained herein are meant to convey that the described embodiments have been actually reduced to practice.

The breadth and scope of the present invention should not be limited by any of the above-described exemplary embodiments, but should be defined only in accordance with the following claims and their equivalents.

What is claimed is:

1. A method of making a semiconductor device, comprising:
forming, on a substrate, a first gate stack having a first gate conductor layer and a first gate dielectric structure between the first gate conductor layer and the substrate;
forming an inter-gate dielectric structure at a sidewall of the first gate conductor, wherein the inter-gate dielectric structure has four or more layers of two or more different dielectric films disposed in an alternating manner;
forming, adjacent to the inter-gate dielectric structure, a second gate stack having a second gate conductor layer and a second gate dielectric structure between the second gate conductor layer and the substrate.

2. The method of claim 1, wherein forming the inter-gate dielectric structure comprises:
forming the four or more layers of dielectric films over the first gate stack and the substrate; and
selectively removing a portion of the layers of dielectric films.

3. The method of claim 1, further comprising forming one or more of the dielectric films of the inter-gate dielectric structure thin enough such that its wet etch rate is significantly less than its bulk etch rate.

4. The method of claim 1, further comprising forming adjacent layers of the dielectric films of the inter-gate dielectric structure having significantly different wet etch rates.

5. The method of claim 1, further comprising forming the layers of dielectric films of the inter-gate dielectric structure using in-situ film deposition.

6. The method of claim 1, further comprising forming the inter-gate dielectric structure with four alternating oxide and nitride films.

7. The method of claim 1, further comprising forming the inter-gate dielectric structure with four alternating nitride and oxide films.

8. The method of claim 6, further comprising forming at least one further layer of oxide film.

9. The method of claim 7, further comprising forming at least one further layer of nitride film.

10. The method of claim 6, further comprising forming at least one further alternating pair of oxide/nitride films.

11. The method of claim 7, further comprising forming at least one further alternating pair of nitride/oxide films.

12. The method of claim 1, further comprising forming the first gate conductor layer as a memory gate of a split-gate memory cell.

13. The method of claim 1, further comprising forming the second gate conductor layer as a select gate of a split-gate memory cell.

14. A semiconductor device, comprising:
a substrate;
a first gate structure having a first gate conducting layer and a first gate dielectric structure between the first gate conducting layer and the substrate;
a second gate structure having a second gate conducting layer and a second gate dielectric structure between the second gate conducting layer and the substrate; and
an inter-gate dielectric structure disposed between the first gate structure and the second gate structure, wherein the inter-gate dielectric structure has four or more layers of two or more different alternating dielectric films.

15. The semiconductor device of claim 14, wherein one or more dielectric films of the inter-gate dielectric structure has a minimal thickness such that its wet etch rate is significantly less than its bulk etch rate.

16. The semiconductor device of claim 14, wherein adjacent layers of the dielectric films of the inter-gate dielectric structure have significantly different wet etch rates.

17. The semiconductor device of claim 14, wherein the inter-gate dielectric structure comprises four alternating oxide and nitride films.

18. The semiconductor device of claim 14, wherein the inter-gate dielectric structure comprises four alternating nitride and oxide films.

19. The semiconductor device of claim 17, wherein the inter-gate dielectric structure comprises at least one further layer of oxide film.

20. The semiconductor device of claim 18, wherein the inter-gate dielectric structure comprises at least one further layer of nitride film.

21. The semiconductor device of claim 17, wherein the inter-gate dielectric structure comprises at least one further alternating pair of oxide/nitride films.

22. The semiconductor device of claim 18, wherein the inter-gate dielectric structure comprises at least one further alternating pair of nitride/oxide films.

23. The semiconductor device of claim 14, wherein the first gate structure comprises a memory gate of a split-gate memory cell.

24. The semiconductor device of claim 14, wherein the second gate structure comprises a select gate of a split-gate memory cell.
